(19) United States
(12) Patent Application Publication
(10) Pub. No.: US 2013/0221444 A1
(43) Pub. Date: Aug. 29, 2013

(54) SEMICONDUCTOR DEVICE AND MANUFACTURING METHOD OF SEMICONDUCTOR DEVICE

(71) Applicant: Hirofumi IGARASHI, Kanagawa-ken (JP)

(72) Inventor: Hirofumi IGARASHI, Kanagawa-ken (JP)

(73) Assignee: KABUSHIKI KAISHA TOSHIBA, Tokyo (JP)

(21) Appl. No.: 13/605,924

(22) Filed: Sep. 6, 2012

(30) Foreign Application Priority Data
Feb. 24, 2012 (JP) P2012-038873

(51) Int. Cl. H01L 27/088; H01L 21/336

(52) U.S. Cl. 257/368; 438/290; 257/E27.06; 257/E21.409

(57) ABSTRACT

According to one embodiment, with gate electrodes and side walls as a mask, oblique ion implanting of the impurity is carried out for the semiconductor substrate, so that channel impurity layers having different dopant concentrations are simultaneously implanted beneath a first and a second gate electrode.

### CROSS-REFERENCE TO RELATED APPLICATION

This application is based upon and claims the benefit of priority from Japanese Patent Application No. 2012-038873, filed Feb. 24, 2012; the entire contents of which are incorporated herein by reference.

### FIELD

Embodiments described herein relate to a semiconductor device and a manufacturing method of the semiconductor device.

### BACKGROUND

To fabricate semiconductor device having multiple, integrated, field-effect transistors having different thresholds for different field-effect transistors, differential channel ion implanting is carried out. In a channel ion implanting operation, the impurity concentration of the channel is increased, so that the inter-band leak becomes more significant. In order to create two different transistors having different threshold voltages using this technique, the first transistor (or region where the channel is formed) must be masked to prevent implanting species from reaching the channel, while the channel of the second transistor is implanted to increase the dopant concentration thereof. Likewise, if the channel of the first transistor is also modified by implant, the second process is reversed to protect the second channel during implant of the first. This protection requires photolithographic or other masking techniques, the requirements of which require excess spacing between the transistors. Additionally, because the leakage in the channel is increased by increasing the dopant concentration, the gate length needs to be extended or lengthened to reduce the likelihood of leakage thorough the channel, which results in larger than desired transistor sizes.

### DESCRIPTION OF THE DRAWINGS

FIG. 1A to FIG. 1E are cross-sectional views illustrating the manufacturing method of the semiconductor device according to a first embodiment.

FIG. 2A to FIG. 2D are cross-sectional views illustrating the manufacturing method of the semiconductor device according to a first embodiment.

FIG. 3A to FIG. 3F are cross-sectional views illustrating the manufacturing method of the semiconductor device according to a second embodiment.

FIG. 4A to FIG. 4E are cross-sectional views illustrating the manufacturing method of the semiconductor device according to a second embodiment.

FIG. 5A to FIG. 5E are cross-sectional views illustrating the manufacturing method of the semiconductor device according to a third embodiment.

FIG. 6A to FIG. 6D are cross-sectional views illustrating the manufacturing method of the semiconductor device according to a third embodiment.

### DETAILED DESCRIPTION

In general, according to one embodiment, the semiconductor device and the manufacturing method of the semiconductor device related to the embodiment will be explained with reference to figures. However, the present disclosure is not limited to the following embodiments.

According to the embodiment, there is provided a semiconductor device and a manufacturing method of the semiconductor device whereby the thresholds of different field-effect transistors are different from each other and, at the same time, an increase in the gate length of the field-effect transistors is suppressed, while an increase in the channel leakage is suppressed.

According to the semiconductor device in the embodiment, there are the first gate electrode, the second gate electrode, the first side wall, the second side wall, the third side wall, the first channel impurity layer, and the second channel impurity layer. The first gate electrode is formed on the first gate insulating film on the semiconductor substrate. The second gate electrode is formed on the second gate insulating film on the semiconductor substrate. The first side wall is formed on the side wall of the first gate electrode. The second side wall is formed on the side wall of the first side wall. The third side wall is formed on the side wall of the second gate electrode. The first channel impurity layer is formed beneath the first gate electrode, using a self-alignment technique with respect to the second side wall. The second channel impurity layer is formed beneath the second gate electrode using a self-alignment technique with respect to the third side wall. The first side wall and the third side wall have the same film thickness, and they are formed on the semiconductor substrate, respectively.

### Embodiment 1

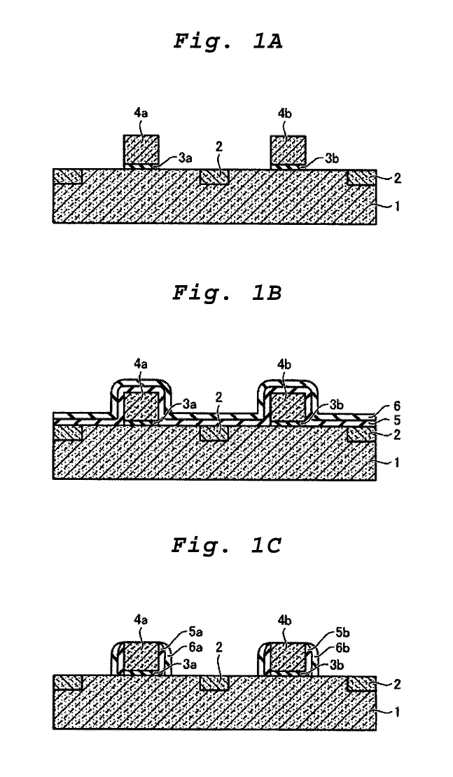

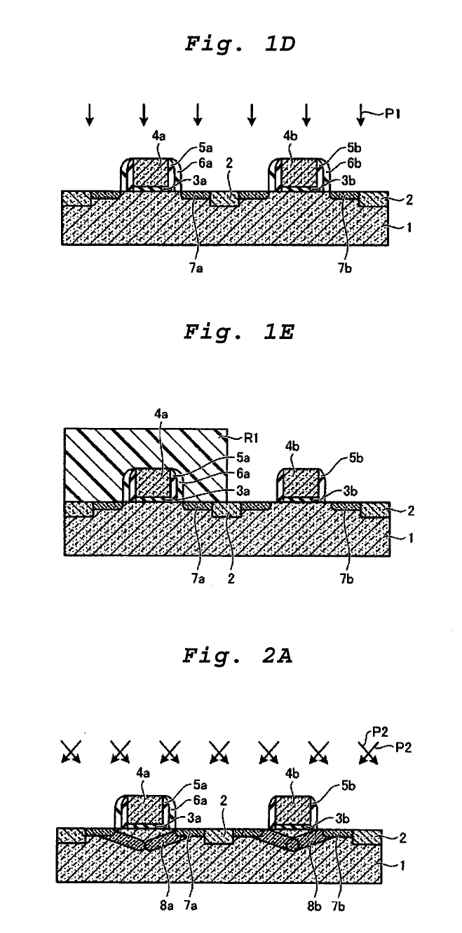

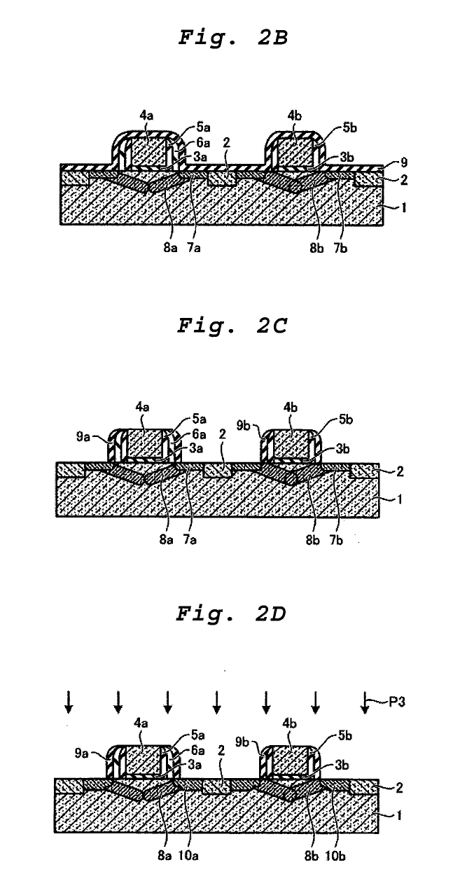

FIG. 1A to FIG. 1E and FIG. 2A to FIG. 2D are cross-sectional views illustrating the manufacturing method of the semiconductor device according to Embodiment 1.

As shown in FIG. 1A, the element separating layer 2 is formed on the semiconductor substrate 1. The material for making the semiconductor substrate 1 can be selected from, for example, Si, Ge, SiGe, SiC, SiSn, PbS, GaAs, InP, GaP, GaN, GaAlAs, GaInAsP, and ZnSe. The material of the element separating layer 2 may be a silicon oxide film. For example, the element separating layer 2 is an STI (Shallow Trench Isolation) structure.

Then, by means of thermal oxidation or some other method, the gate insulating films 3a, 3b are formed on the semiconductor substrate 1. Also, the effective film thicknesses of the gate insulating films 3a, 3b are equal to each other. Also, the material for forming the gate insulating films 3a, 3b may be a silicon oxide film. However, they may also be made of Hf or some other high dielectric constant film deposited by CVD methods.

Then, after the gate electrode material is formed on the semiconductor substrate 1 using the CVD or some other method, photolithography and etching technology are used to pattern, together, or sequentially in separate steps, the gate electrode 4a, 4b from the layer of the gate electrode material and the gate insulator 3a, 3b from the gate insulator material. As a result, the gate electrodes 4a, 4b are formed over the gate insulating films 3a, 3b on the semiconductor substrate 1. In addition, the gate lengths of the gate electrodes 4a, 4b are equal to each other by patterning the etch mask to provide equal areas of each of the gate insulators 3a, 3b and gate electrodes 4a, 4b. Here, the material used for making the gate electrodes 4a, 4b may be a polysilicon film. However, one may also use W or some other metal, silicide, or some other alloy.

Then, as shown in FIG. 1B, a CVD (chemical vapor deposition) or other method is used to form an insulating film 5 on the semiconductor substrate 1 and thereby cover the gate electrodes 4a, 4b. In addition, using CVD or some other deposition method, an insulating film 6 is formed on the insulating film 5. In addition, the materials of the insulating films 5, 6 are selected to have different etching rates. For example, when a silicon oxide film is used as the insulating film 5, a silicon nitride film may be used as the insulating film 6.

Then, as shown in FIG. 1C, by performing anisotropic etching of the insulating films 5, 6, a side wall 5a is formed on the side wall of the gate electrode 4a, and a side wall 6a is formed over the side wall 5a, and the insulating films are etched off of the field (upper surface) of the substrate and upper surface of the electrodes 4a, 4b. This results in the formation of side walls 5b and 6b on the side walls of the gate electrode 4b, and of side walls 5a and 6a on the side walls of electrode 4a.

Then, as shown in FIG. 1D, using the gate electrodes 4a, 4b and side walls 5a, 5b, 6a, 6b as an in situ mask, ion implanting P1 of a dopant is performed on the semiconductor substrate 1, so that an LDD layer 7a is formed in the upper surface of the substrate adjacent to either side of the gate electrodes 4a, 4b and spaced from the base of the gate electrodes 4a, 4b by the width of the side walls 5a, 6a and 5b, 6b. Thus, the LDD regions are physically isolated from the electrode by the combined side wall widths. Alternatively, the LDD layers 7a, 7b may be formed before formation of the side walls 5a, 6a, 5b, 6b.

Then, as shown in FIG. 1E, using photolithography, a resist pattern R1 is formed on the semiconductor substrate 1, so that while the gate electrode 4a and side walls 5a, 6a are covered and thus protected, the gate electrode 4b and side walls 5b, 6b are exposed to an etchant, and by selectively etching the side wall 6b, the side wall 6b is removed from the side wall 5b.

Then, as shown in FIG. 2A, the resist pattern R1 is removed. To form the doped channel, using the gate electrodes 4a, 4b and side walls 5a, 6a, 5b as a mask, the oblique or angled ion implanting P2 of the channel dopant is performed on the semiconductor substrate 1, so that a channel impurity layer 8a is formed beneath the gate electrode 4a on the semiconductor substrate 1 and simultaneously, the channel impurity layer 8b is formed beneath the gate electrode 4b on the semiconductor substrate 1. The angle for the oblique ion implanting P2 is in this embodiment selected to be in the range of, for example, 30° to 45°.

By using the electrodes and sidewalls as an in situ mask, the channel impurity layer 8a is formed on the semiconductor substrate 1 in a self-alignment way with respect to the side wall 6a, and the channel impurity layer 8b is formed on the semiconductor substrate 1 in a self-alignment way with respect to the side wall 5b.

Here, because the side wall 6b is removed at the side wall of the gate electrode 4b, the film thickness of the side wall 5b of the gate electrode 4b is thinner than the overall film thickness of the side walls 5a, 6a of the gate electrode 4a. Because the dopants are implanted at a relatively shallow angle, on the order of 30 to 45 degrees with respect to the plane of the substrate 11, the dopants enter the substrate at the exposed regions thereof adjacent to, and outwardly of, the protective side wall layers. Because, in this embodiment, the electrode 4a has two side walls, but electrode 4b has only one, the entry location of the dopants is one side wall thickness (side wall 5a) closer to the center of the electrode 5b as compared to the entry point of the dopants implanted below electrode 5a. As a result, using dopant ion energies capable of reaching the center of the electrode 5b but not significantly deeper into the substrate 1, a higher concentration of dopant under the center of electrode 4b than electrode 4a results and is caused by dopants reaching the center of channel 8b from both sides of the electrode 4b, whereas, as a result of the additional wall 5a thickness on electrode 4a, the dopants do not overlap in the center of the channel 8a. Consequently, the dopant concentration in the doped channel 8a beneath the gate electrode 4a is lower than the dopant concentration in the doped channel layer 8b beneath the gate electrode 4b. The threshold voltage of the field-effect transistor using the gate electrode 4a is thus lower than the threshold voltage of the field-effect transistor using the gate electrode 4b.

Additionally, because the channel doping is carried out at an implant angle the resulting doping profile is, in contrast to a channel doped using traditional implant, wherein the dopant ions are substantially perpendicular to the substrate surface, the span or length of the doped region is angled with respect to the underside of the electrode and gate insulator. Referring again to FIG. 2A, it can be seen that the doped regions 8a, 8b extend under the gate insulating layers 3a, 3b, starting at the surface of the substrate 1 adjacent to the gate insulating layer 3a or 3b, and extending inwardly of the gate insulating layer 3a or 3b and simultaneously inwardly of the substrate, such that an undoped region within the substrate extends between the central region of the doped channels 8a, 8b and the adjacent underside of the respective gate insulating layer 3a, 3b and gate electrode 4a and 4b.

Then, as shown in FIG. 2B, to form the source and drain regions, a CVD or other thin film formation method is employed to form the insulating film 9 on the semiconductor substrate 1 to cover the substrate 1 field and gate electrodes 4a, 4b, which is to be configured as an in situ mask. Here, as the material of the insulating film 9, for example, a silicon oxide film or a silicon nitride film can be used.

Then, as shown in FIG. 2C, by carrying out anisotropic etching of the insulating film 9, a the side wall 9a is formed on the side wall 6a, and a side wall 9b is formed on the side wall 5b while the remainder of the insulating film is etched from the field and the top of the electrodes 4a, 4b.

Then, as shown in FIG. 2D, with gate electrodes 4a, 4b and side walls 5a, 5b, 6a, 9a, 9b forming an in situ mask, ion implanting P3 of a dopant is carried out on the semiconductor substrate 1, to form the source/drain layers 10a, 10b arranged on the sides of the gate electrodes 4a, 4b, and these source drain regions are spaced from the electrode by the in situ masking of the side walls 5a, 6a and 9a and 5b and 9b. Here, as the impurity, B, P, As, etc., may be used.

As the channel impurity layers 8a, 8b are formed on the semiconductor substrate 1 by the oblique ion implanting P2, the dopant concentration of the doped channels 8a, 8b at the boundary portion between the channel region formed beneath the gate electrodes 4a, 4b and the source/drain layers 10a, 10b (FIG. 2D) will be lower than that of the central portion of the channel region, and thus cross channel leakage.

In addition, in contrast to prior processes, there is no need to carry out the ion implanting separately, using alternating masking and implant steps to protect one channel region while the other channel is implanted, to ensure different impurity concentrations for the channel impurity layers 8a, 8b, because the in situ masking as between the first electrode 4a having two side walls, and the second electrode having only one side wall, resulting in different doping concentrations in their respective channels using the same implant step. Consequently, when the channel impurity layer 8a is formed beneath the gate electrode 4a, there is no need to cover the periphery of the gate electrode 4b with a resist. Consequently, the spacing between the gate electrodes 4a, 4b can be reduced corresponding to absence of shadowing that would be caused by the resist in the oblique ion implanting P2. As a result, it is possible to improve the scale of integration, i.e., reduce the spacing between, the adjacent field-effect transistors having different channel doping concentrations.

### Embodiment 2

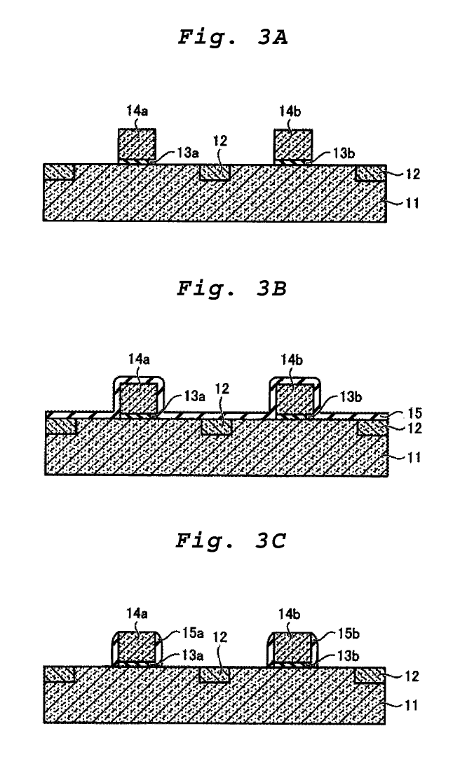

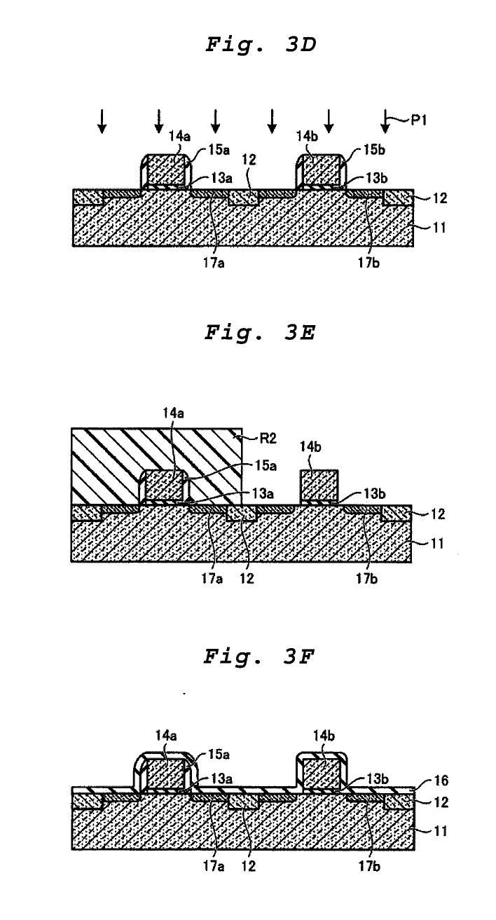

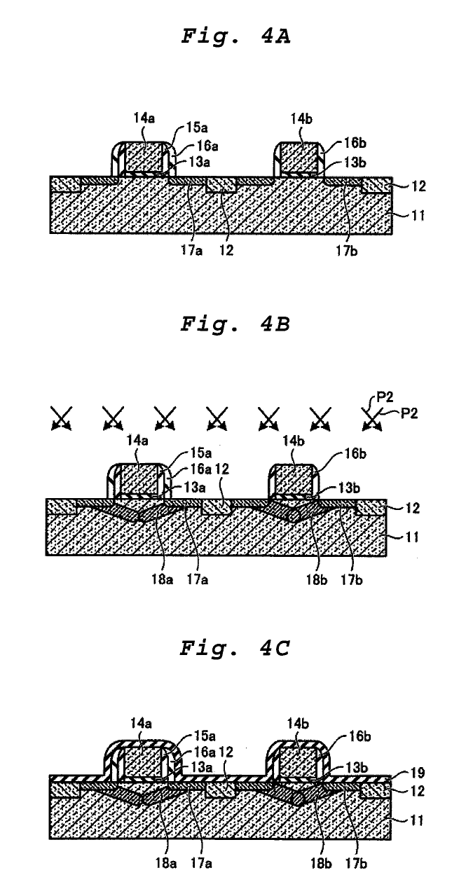

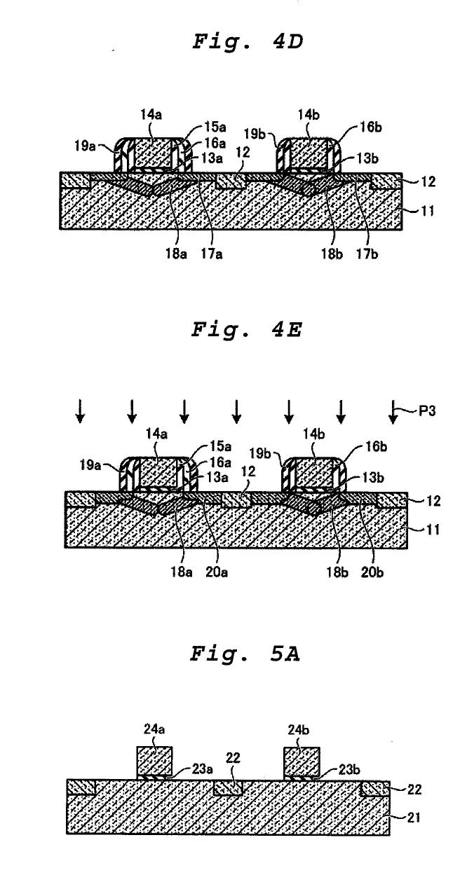

FIG. 3A to FIG. 3F and FIG. 4A to FIG. 4E are cross-sectional views illustrating the manufacturing method of the semiconductor device according to Embodiment 2.

As shown in FIG. 3A, an element separating layer 12, such as a shallow trench isolating structure, is formed in the semiconductor substrate 11. Then, after a gate insulating films and a gate electrodes film are formed on the semiconductor substrate 11, the insulator and electrode films are pattern etched to provide the gate insulators 13a, 13b and the gate electrodes 14a, 14b thereover. The gate insulator film may be pattern etched to form the gate insulators 13a, 13b before the gate electrode layer is deposited, or both films bay be deposited and the stack thereof etched to form the gate electrodes over the gate insulators

Then, as shown in FIG. 3B, using a CVD method or the like, an insulating film 15 is formed on the semiconductor substrate 11 and over the gate electrodes 14a, 14b. Thereafter, as shown in FIG. 3C, by anisotropically etching of the insulating film 15 to remove it from the substrate field and the top of the gate electrodes 14a, 14b, a side wall 15a of the remaining insulating film 15 is formed on the side walls of the gate electrode 14a and, at the same time, a side wall 15b of remaining insulating film 15 is formed on the side walls of the gate electrode 14b.

Then, as shown in FIG. 3D, with gate electrodes 14a, 14b and side walls 15a, 15b serving as an in situ mask, ion implanting P1 of a dopant is carried out on the semiconductor substrate 11, so that an LDD layer 17a is implanted into the substrate adjacent to the gate electrode 14a and spaced therefrom by the side wall 15a and simultaneously an LDD layer 17b is implanted into the substrate adjacent to the gate electrode 14b and spaced therefrom by the side wall 15b.

As shown in FIG. 3E, using photolithography, a resist pattern R2 is formed on the semiconductor substrate 11 to cover the gate electrode 14a and side wall 15a thereof, but leave exposed the gate electrode 14b and side wall 15b. Then, by selectively etching off the side wall 15b, the side wall 15b is removed from the side wall of the gate electrode 14b.

Thereafter, the resist pattern R2 is removed and as shown in FIG. 3F, an insulating film 16 is deposited on the semiconductor substrate 11 to cover the gate electrodes 14a, 14b and field of the substrate 11 using CVD or another deposition technique.

Then, as shown in FIG. 4A, by performing anisotropic etching of the insulating film 16 to remove the insulating film from the substrate 11 field and top of the electrodes 13a, 13b, a side wall 16a is formed from remaining insulating film 16 on the side wall 15a; at the same time and a side wall 16b is formed from remaining insulating film 16 on the side wall of the gate electrode 14b. Here, the materials of the side walls 15a, 15b and side walls 16a, 16b may be the same or different from each other.

Then, as shown in FIG. 4B, using the gate electrodes 14a, 14b and side walls 15a, 16a, 16b as an in situ mask, oblique or angle ion implanting P2 of a dopant is carried out to implant a doped channel 18a and a doped channel layer 18b beneath the gate electrode.

Using this technique, the doped channel layer 18a is self aligned to the side wall 16a and the doped channel 18b self-aligned to side wall 16b.

Then, as shown in FIG. 4C, using a CVD or other layer forming method, an insulating film 19 is formed on the semiconductor substrate 11 to cover the gate electrodes 14a, 14b and the substrate 11 field.

Then, as shown in FIG. 4D, by performing anisotropic etching of the insulating film 19, a side wall 19a is formed on the side wall 16a and a side wall 19b is formed on the side wall 16b.

Then, as shown in FIG. 4E, using the gate electrodes 14a, 14b and side walls 15a, 16a, 16b, 19a, 19b as an in situ mask, the ion implanting P3 of impurity dopant is carried out for the semiconductor substrate 11, to form source/drain layer 20a implanted in the substrate 11 adjacent to, the side of the gate electrode 14a and spaced therefrom by the side walls 15a, 16a, 19a, and the source/drain layer 20b implanted in substrate 11 adjacent to the gate electrode 14b and spaced therefrom by the side walls 16b, 19b.

Here, LDD layers 17a, 17b are self-aligned with respect to the side walls 15a, 15b, and the channel impurity layers 18a, 18b are self-aligned with respect to the side walls 16a, 16b, respectively, so that it is possible to independently set the positions of the LDD layers 17a, 17b and the positions of the channel impurity layers 18a, 18b.

### Embodiment 3

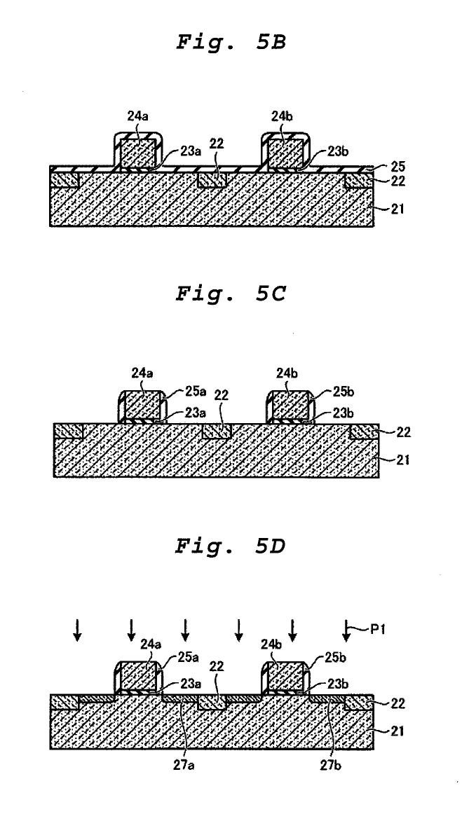

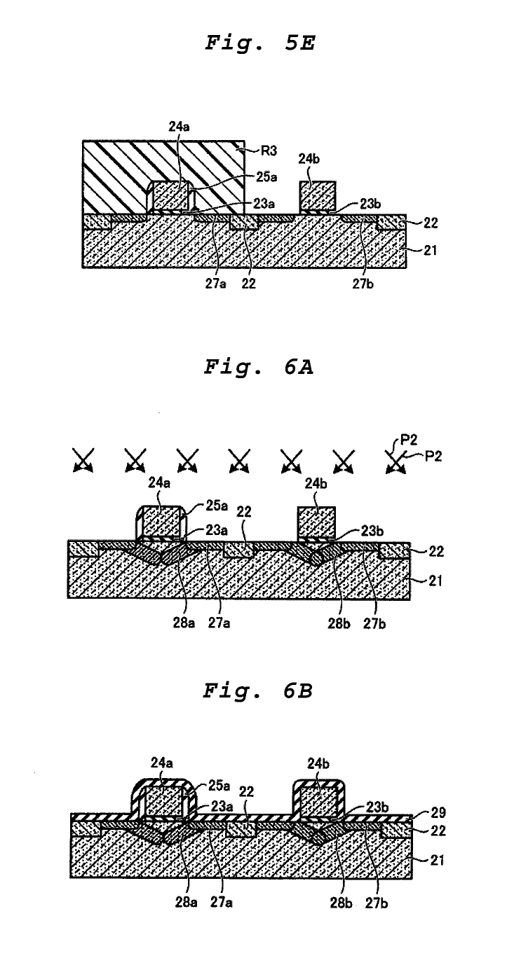

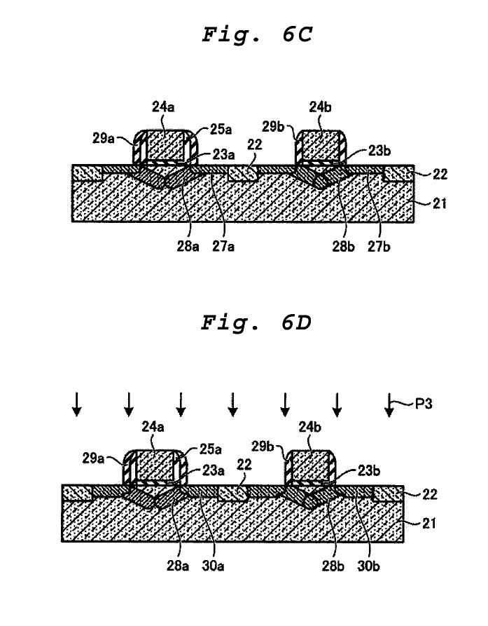

FIG. 5A to FIG. 5E and FIG. 6A to FIG. 6D are cross-sectional views illustrating the manufacturing method of the semiconductor device according to Embodiment 3.

As shown in FIG. 5A, an element separating layer 22, such as an STI structure, is formed on the semiconductor substrate 21. Then, after the gate insulating films 23a, 23b are formed on the semiconductor substrate 21 such as by deposition and patterning of an insulating film, gate electrodes 24a, 24b are formed on the semiconductor substrate 21 over the gate insulating films 23a, 23b such as by blanket deposition of an electrode material followed by patterned etching thereof.

Then, as shown in FIG. 5B, using CVD or another layer forming method, an insulating film 25 is formed on the semiconductor substrate 21 to cover the gate electrodes 24a, 24b and field of the substrate 21.

Then, as shown in FIG. 5C, by anisotropically etching the insulating film 25, a side wall 25a is formed on the side wall of the gate electrode 24a and a side wall 25b is formed on the side wall of the gate electrode 24b.

Then, as shown in FIG. 5D, using the gate electrodes 24a, 24b and side walls 25a, 25b as a mask, ion implanting P1 of a dopant is carried to implant an LDD layer 27a into the substrate adjacent to the side of the gate electrode 24a and spaced therefrom by the side wall 25a and an LDD layer 27b is implanted into the substrate 21 adjacent to the side of the gate electrode 24b and spaced therefrom by the side wall 25b. Alternatively, one may also use a scheme in which the LDD layers 27a, 27b are formed in the stage shown in FIG. 5A before formation of the side walls 25a, 25b.

Then, as shown in FIG. 5E, using photolithographic techniques, a resist pattern R3 is formed on the semiconductor substrate 21 to cover the gate electrode 24a and side wall 25a but leave the gate electrode 24b and side wall 25b are exposed. Thereafter, by selectively etching off the side wall 25b, the side wall 25b is removed from the side wall of the gate electrode 24b.

Then, the resist pattern R3 is removed, and as shown in FIG. 6A, using the gate electrodes 24a, 24b and side wall 25a as an in situ mask, oblique or angled ion implanting P2 of a dopant is carried out on the semiconductor substrate 21, so that a doped channel 28a arranged beneath the gate electrode 24a is formed in the semiconductor substrate 21 and a doped channel 28b arranged beneath the gate electrode 24b is formed in the semiconductor substrate 21.

The doped channel layer 28a is self-aligned with respect to the side wall 25a, and the doped channel 28b is self-aligned way with respect to the gate electrode 24b. In addition, a protective film may be formed on the semiconductor substrate 21 to cover the entirety of the gate electrodes 24a, 24b before carrying out the oblique ion implanting P2 in order to suppress damage to the gate electrodes 24a, 24b due to the oblique ion implanting P2. For example, a silicon oxide film may be used as the protective film.

Then, as shown in FIG. 6B, using CVD or another film forming method, an insulating film 29 is formed on the semiconductor substrate 21 to cover the gate electrodes 24a, 24b.

Then, as shown in FIG. 6C, by anisotropically etching of the insulating film 29, a side wall 29a is formed on the side wall 25a and a side wall 29b is formed on the side wall of the gate electrode 24b from the remnants of the insulating film 29.

Then, as shown in FIG. 6D, using the gate electrodes 24a, 24b and side walls 25a, 29a, 29b as an in situ mask, ion implanting P3 of a dopant is carried out, to implant a source/drain layer 30a into the substrate 21 adjacent to the side of the gate electrode 24a and spaced therefrom by side walls 25a, 29a and a source/drain layer 30b is implanted into the substrate adjacent to the side of the gate electrode 24b and spaced therefrom by the side wall 29b. Here, the materials of the side walls 25a, 29a, 29b may be the same or different from each other.

Here, by forming channel impurity layers 28a, 28b without setting the side wall 25b on the gate electrode 24b, there is no need to form the side wall 25a with a laminated structure made of materials having different etching rates, and the side walls 25a, 29a, 29b may be formed from the same material.

In all embodiments described herein, because the channel impurity layers/doped channels are formed on the semiconductor substrate 1 by angled ion implanting of the dopant species, the dopant concentration of the doped channels, at the boundary portion between the channel region formed beneath the gate electrodes and the source/drain layers will be lower than that at the central portion of the channel region, and thus cross channel leakage will be reduced.

In addition, in contrast to prior processes, there is no need to carry out the ion implanting separately for the two different transistors, using alternating masking and implant steps to protect one channel region while the other channel is implanted, to ensure different impurity concentrations for the different channel impurity layers/doped channels, because the differences in the width of the in situ masking as between the first electrode and side wall(s), and the second electrode and, where used, side wall(s), results in different doping concentrations in their respective channels using the same implant step. Consequently, when the channel impurity layer is formed beneath the gate electrode on one transistor, such as the “a” side transistor of the embodiments herein, there is no need to cover the periphery of the gate electrode on the “b” side with a resist. Consequently, the spacing between the gate electrodes can be reduced corresponding to absence of shadowing that would be caused by the resist in the oblique ion implanting P2. Thus, it is possible to improve the scale of integration, i.e., reduce the spacing between, the adjacent field-effect transistors having different channel doping concentrations.

Also, as is present in embodiment 1, the 2^{nd} and third embodiments herein all share the feature that the doped channel extends inwardly of the substrate as it extends under the gate insulating layer and the gate electrode of the gate, such that an undoped region extends within the substrate, after the angle implant into the channel region, between the channel and the overlying gate insulating layer and gate electrode, between the central region of the channel and the gate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
A substrate;
a first gate having a first doped channel region and a second gate having a second doped channel region, electrode formed on the substrate, wherein the first doped channel regions and the second doped channel regions extend from a location adjacent to the surface of the substrate at the edge of the gate, to a location, near the center of the gate, wherein the doped layer is spaced inwardly of the substrate; and
the first doped channel has a smaller concentration of dopant species than the second doped channel.

2. The semiconductor device of claim 1, wherein the first and the second gates include a gate insulating layer formed over the gate.

3. The semiconductor device of claim 3, further including a gate electrode formed over the gate insulating layer.

4. The semiconductor device of claim 1, further including at least one source or drain region disposed adjacent to, and spaced from, the gate.

5. The semiconductor device of claim 1, wherein the concentration of dopant species in at least one of the channels, at a position underlying the center region of the gate, is greater than the concentration of dopant species in other portions of the channel.

6. The semiconductor device of claim 4, wherein the source of drain region is self aligned with respect to the gate.

7. The semiconductor device of claim 4, wherein the doped channel extends, adjacent the surface of the substrate, between the gate and the source or drain region.

8. The semiconductor device of claim 7, wherein a wall on the side of the gate electrode and gate insulating layer extends over a portion of the doped channel.

9. The semiconductor device of claim 1, wherein the first and second channel regions are implanted simultaneously, but have different dopant concentrations at the center thereof.

10. The semiconductor device of claim 1, wherein the first and second channel regions are implanted simultaneously, but have different dopant concentration gradients, as considered from the edge to the center of the first and the second doped channels.

11. A method for manufacturing a semiconductor device, comprising the steps of:
forming first and second gate electrodes on a semiconductor substrate;
forming at least one sidewall on at least one of the first and the second gate electrodes, such that the length across the first gate electrode and any walls formed thereon is greater than the length across the second gate electrode and any walls thereon;
using the first and second gate electrodes, and any walls thereon, as a mask for performing angle ion implanting on the semiconductor substrate, so that a first channel dopant layer is implanted into the substrate in a location beneath the first gate electrode and a second channel impurity layer is simultaneously implanted into the substrate at a location beneath the second gate.

12. The method of claim 11, wherein the first channel dopant layer and the second channel dopant layer have different dopant concentrations.

13. The method of claim 11, wherein the first channel dopant layer and the second channel dopant layer have different dopant concentration gradients across the channel.

14. The method of claim 11, wherein there is one wall on the first electrode and no wall on the second electrode, during the angle implantation of the first and the second doped channel impurity layers.

15. The method of claim 11, where there are two walls on the first electrode and one wall on the second electrode, during the angle implantation of the first and the second doped channel impurity layers.

16. The method of claim 11, wherein a source or a drain are formed in the substrate adjacent to, but spaced from, and adjacent electrode.

17. The method of claim 16, wherein the angle implanted channel dopant layer is implanted into the substrate between the source or drain and the adjacent electrode.

18. The method of claim 11, wherein an undoped area extends between the channel dopant layer and the middle of the electrode.

19. The method of claim 11, wherein a gate insulating layer is deposited prior to depositing the gate electrode layer.

20. The method of claim 11, wherein the difference in the number of sidewalls on the first electrode and the second electrode is provided by forming a sidewall on both the first and the second electrodes and selectively removing the sidewall from only the second electrode.
